(19) United States
(12) Patent Application Publication
(10) Pub. No.: US 2026/0018984 A1
(43) Pub. Date: Jan. 15, 2026

(54) POWER CONVERTER FOR ADAPTIVELY ADJUSTING FREQUENCY

(71) Applicant: ANPEC ELECTRONICS CORPORATION, HSINCHU (TW)

(72) Inventors: TSANG-YUNG CHEN, HSINCHU (TW); CHUN-KAI HSU, HSINCHU CITY (TW); CHIH-HENG SU, Hsinchu City (TW)

(21) Appl. No.: 18/921,014

(22) Filed: Oct. 21, 2024

(30) Foreign Application Priority Data
Jul. 10, 2024 (TW) 113125738

(51) Int. Cl. H02M 1/00; H02M 1/14; H02M 3/158; H03K 5/156

(52) U.S. Cl. CPC H02M 1/0025; H02M 1/14; H02M 3/158; H03K 5/1565

(57) ABSTRACT

A power converter for adaptively adjusting a frequency is provided. The power converter includes a high-side switch, a low-side switch, a feedback circuit, a frequency adjusting circuit, a control circuit and a driver circuit. The feedback circuit outputs a regulation on-time signal according to a voltage signal of a node between a second terminal of an inductor and a first terminal of a capacitor. When the frequency adjusting circuit determines that a duty cycle of a waveform of the regulation on-time signal is not larger than a duty cycle of a waveform of a minimum on-time signal, the frequency adjusting circuit adjusts a frequency of a clock signal. The control circuit outputs a control signal according to the adjusted clock signal. The driver circuit drives the high-side switch and the low-side switch according to the control signal.

### CROSS-REFERENCE TO RELATED PATENT APPLICATION

This application claims the benefit of priority to Taiwan Patent Application No. 113125738, filed on Jul. 10, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a power converter, and more particularly to a power converter for adaptively adjusting a frequency.

### BACKGROUND OF THE DISCLOSURE

Power converters are indispensable for electronic devices. The power converters are used to adjust power and supply the adjusted power to the electronic devices. A high-side switch and a low side switch of the power converter must be switched according to voltages or currents of circuit components in the power converter such that the power converter supplies appropriate power to a load. However, in a conventional power converter, a driver circuit switches the high-side switch and the low-side switch at a constant frequency. Therefore, when an input voltage of the conventional power converter is increased or decreased, the conventional power converter supplies an output voltage signal having unstable voltages or ripple waves.

### SUMMARY OF THE DISCLOSURE

In response to the above-referenced technical inadequacies, the present disclosure provides a power converter for adaptively adjusting a frequency. The power converter includes a high-side switch, a low-side switch, a feedback circuit, a frequency adjusting circuit, a control circuit and a driver circuit. A first terminal of the high-side switch is coupled with an input voltage. A first terminal of the low-side switch is connected to a second terminal of the low-side switch. A second terminal of the low-side switch is grounded. A node between the first terminal of the low-side switch and the second terminal of the high-side switch is connected to a first terminal of an inductor. A second terminal of the inductor is connected to a first terminal of a capacitor. A second terminal of the capacitor is grounded. The feedback circuit is connected to a node between the second terminal of the inductor and the first terminal of the capacitor. The feedback circuit is configured to output a regulation on-time signal according to a voltage signal of the node between the second terminal of the inductor and the first terminal of the capacitor. The frequency adjusting circuit is connected to the feedback circuit. When the frequency adjusting circuit determines that a duty cycle of a waveform of the regulation on-time signal is not larger than a duty cycle of a waveform of a minimum on-time signal, the frequency adjusting circuit adjusts a frequency of a clock signal and outputs the clock signal having the frequency that is adjusted. The control circuit is connected to the frequency adjusting circuit. The control circuit is configured to output a control signal according to the clock signal from the frequency adjusting circuit. The driver circuit is connected to the control circuit, a control terminal of the high-side switch and a control terminal of the low-side switch. The driver circuit is configured to drive the high-side switch and the low-side switch according to the control signal from the control circuit.

As described above, the present disclosure provides the power converter for adaptively adjusting the frequency. In the power converter of the present disclosure, the frequency of switching the high-side switch and the low-side switch is able to be appropriately adjusted along with a change in the input voltage. Under this condition, soft switching is able to be efficiently performed on the high-side switch and the low-side switch, so as to prevent instantaneous drops in the output voltage of the power converter of the present disclosure. As a result, the number of ripple waves in the output voltage of the power converter of the present disclosure is reduced. Therefore, stability of the output voltage of the power converter of the present disclosure is improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a block diagram of a power converter for adaptively adjusting a frequency according to a first embodiment of the present disclosure;

FIG. 2 is a block diagram of a power converter for adaptively adjusting a frequency according to a second embodiment of the present disclosure;

FIG. 3 is a block diagram of a frequency adjusting circuit of the power converter for adaptively adjusting the frequency according to the second embodiment of the present disclosure;

FIG. 4 is a flowchart diagram of the power converter for adaptively adjusting the frequency according to the second embodiment of the present disclosure;

FIG. 5 is a waveform diagram of signals of the first and second embodiments of the power converter and a conventional power converter; and

FIG. 6 is a waveform diagram of signals of the first and second embodiments of the power converter and the conventional power converter.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

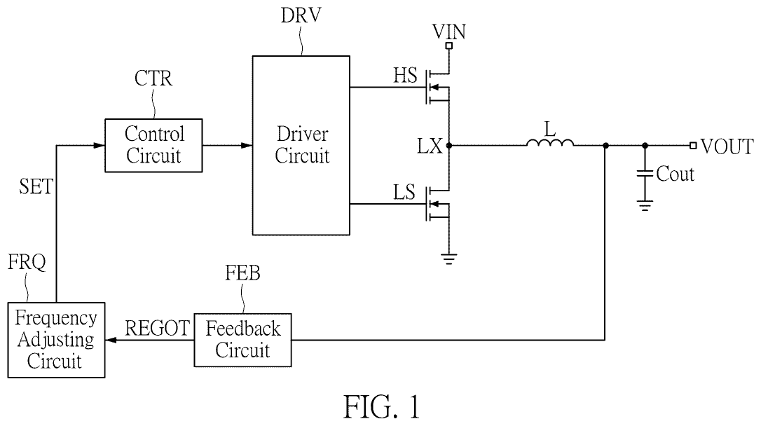

Reference is made to FIG. 1, which is a block diagram of a power converter for adaptively adjusting a frequency according to a first embodiment of the present disclosure.

As shown in FIG. 1, in the first embodiment, the power converter of the present disclosure includes a high-side switch HS, a low-side switch LS, a feedback circuit FEB, a frequency adjusting circuit FRQ, a control circuit CTR and a driver circuit DRV.

A first terminal of the high-side switch HS is coupled with an input voltage VIN. A first terminal of the low-side switch LS is connected to a second terminal of the low-side switch LS. A second terminal of the low-side switch LS is grounded. A node LX between the first terminal of the low-side switch LS and the second terminal of the low-side switch LS is connected to a first terminal of an inductor L. A second terminal of the inductor L is connected to a first terminal of the capacitor Cout. A second terminal of the capacitor Cout is grounded.

The frequency adjusting circuit FRQ is connected to the feedback circuit FEB and the control circuit CTR.

The driver circuit DRV is connected to the control circuit CTR, a control terminal of the high-side switch HS, and a control terminal of the low-side switch LS.

The control circuit CTR outputs a control signal to the driver circuit DRV. The driver circuit DRV, according to the control signal from the control circuit CTR, outputs a high-side on-time signal to the control terminal of the high-side switch HS for driving the high-side switch HS, and outputs a low-side on-time signal to the control terminal of the low-side switch LS for driving the low-side switch LS.

When the driver circuit DRV drives the high-side switch HS and the low-side switch LS, an output voltage VOUT of an output terminal of the power converter (that is, a node between the second terminal of the inductor L and the first terminal of the capacitor Cout) is changed along with a change in an on-time of the high-side switch HS, a change in an on-time of the low-side switch LS and a change in the input voltage VIN coupled with the first terminal of the high-side switch HS.

The node between the second terminal of the inductor L and the first terminal of the capacitor Cout may be connected to the feedback circuit FEB as a feedback node. The feedback circuit FEB outputs a regulation on-time signal REGOT according to a voltage signal of the feedback node.

The frequency adjusting circuit FRQ respectively compares a duty cycle of each of a plurality of waveforms of the regulation on-time signal REGOT from the feedback circuit FEB with the minimum on-time signal.

It should be understood that, a working period of each of the plurality of waveforms of the minimum on-time signal is a minimum on-time of the high-side switch HS. A duty cycle of the waveform of the minimum on-time signal is a ratio of the working period of the waveform of the minimum on-time signal to an entire period of the waveform of the minimum on-time signal. An on-time of the high-side switch HS cannot be smaller than the minimum on-time described above.

When the frequency adjusting circuit FRQ determines that the duty cycle of the waveform of the regulation on-time signal REGOT is larger than the duty cycle of the waveform of the minimum on-time signal, the frequency adjusting circuit FRQ does not adjust or reduce a frequency of a pulse wave of a clock signal SET and directly outputs the clock signal SET that is not adjusted or reduced to the control circuit CTR. The frequency of the pulse wave of the clock signal SET is a preset frequency.

It is worth noting that, when the frequency adjusting circuit FRQ determines that the duty cycle of the waveform of the regulation on-time signal REGOT is not larger than the duty cycle of the waveform of the minimum on-time signal, the frequency adjusting circuit FRQ adjusts the frequency of the pulse wave of the clock signal SET. For example, the frequency adjusting circuit FRQ reduces the frequency of the pulse wave of the clock signal SET and outputs the clock signal SET that is reduced.

The control circuit CTR sets or adjusts the control signal according to the clock signal SET from the frequency adjusting circuit FRQ, and outputs the control signal that is set or adjusted to the driver circuit DRV.

For example, the control circuit CTR sets a width of a pulse wave of a pulse width modulation signal according to the frequency of the clock signal SET from the frequency adjusting circuit FRQ, and outputs the pulse width modulation signal as the control signal to the driver circuit DRV.

The driver circuit DRV sets or adjusts the high-side on-time signal and the low-side on-time signal according to the control signal from the control circuit CTR. The driver circuit DRV outputs the high-side on-time signal that is set or adjusted to the control terminal of the high-side switch HS, and outputs the low-side on-time signal that is set or adjusted to the control terminal of the low-side switch LS.

Within a working period of the high-side on-time signal (that is aligned with a non-working period the low-side on-time signal), the high-side switch HS is turned on and the low-side switch LS is turned off. Conversely, within a non-working period of the high-side on-time signal (that is aligned with a working period the low-side on-time signal), the high-side switch HS is turned off and the low-side switch LS is turned on.

The driver circuit DRV may alternately turn on the high-side switch HS and the low-side switch LS.

The output voltage VOUT of the output terminal of the power converter (that is, the node between the second terminal of the inductor L and the first terminal of the capacitor Cout) is changed along with the change in the input voltage VIN coupled with the first terminal of the high-side switch HS. In the power converter of the present disclosure, the frequency of the pulse wave of the clock signal SET is set or adjusted according to the output voltage VOUT of the power converter of the present disclosure. As a result, the on-time of the high-side switch HS, the on-time of the low-side switch LS, and a switching frequency of the high-side switch HS and the low-side switch LS are set or adjusted for adjusting the output voltage VOUT of the power converter of the present disclosure.

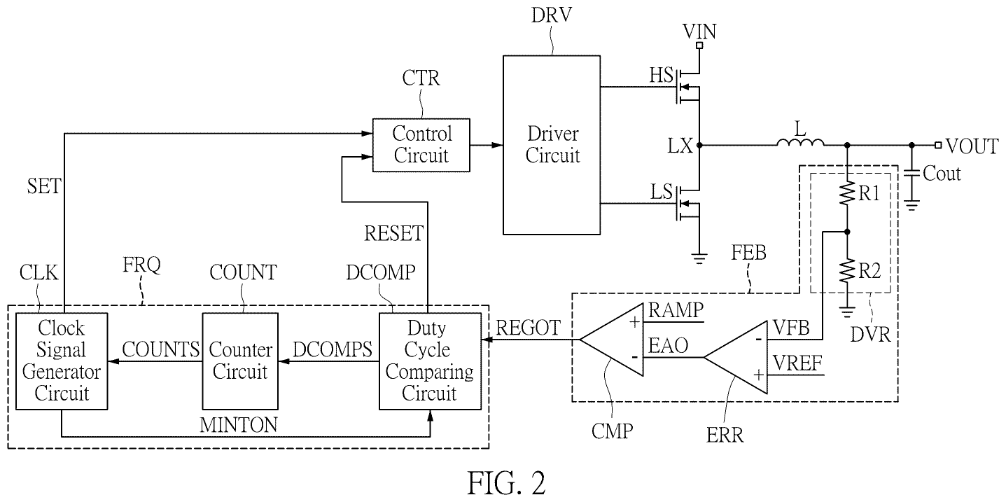

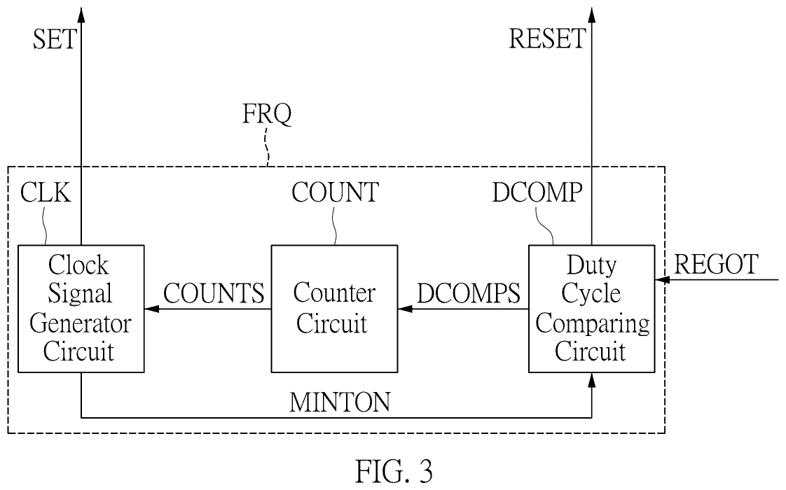

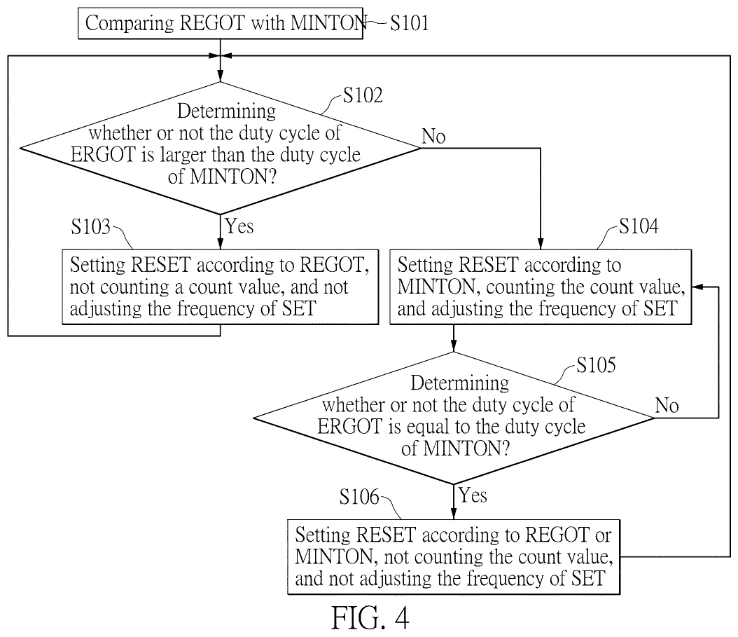

Reference is made to FIG. 2 to FIG. 4, in which FIG. 2 is a block diagram of a power converter for adaptively adjusting a frequency according to a second embodiment of the present disclosure, FIG. 3 is a block diagram of a frequency adjusting circuit of the power converter for adaptively adjusting the frequency according to the second embodiment of the present disclosure, and FIG. 4 is a flowchart diagram of the power converter for adaptively adjusting the frequency according to the second embodiment of the present disclosure.

The power converter of the present disclosure includes the high-side switch HS, the low-side switch LS, the feedback circuit FEB, the frequency adjusting circuit FRQ, the control circuit CTR and the driver circuit DRV as shown in FIG. 2.

As shown in FIG. 2, in the second embodiment, the feedback circuit FEB includes an error amplifier ERR, a comparator CMP and a voltage divider circuit DVR. In practice, the voltage divider circuit DVR may be omitted.

It is worth noting that, as shown in FIG. 2 and FIG. 3, in the second embodiment, the frequency adjusting circuit FRQ includes a duty cycle comparing circuit DCOMP, a counter circuit COUNT and a clock signal generator circuit CLK.

The first terminal of the high-side switch HS is coupled with the input voltage VIN.

The first terminal of the low-side switch LS is connected to the second terminal of the low-side switch LS. The second terminal of the low-side switch LS is grounded. The node LX between the first terminal of the low-side switch LS and the second terminal of the low-side switch LS is connected to the first terminal of the inductor L. The second terminal of the inductor L is connected to the first terminal of the capacitor Cout. The second terminal of the capacitor Cout is grounded.

An input terminal of the driver circuit DRV is connected to the node between the second terminal of the inductor L and the first terminal of the capacitor Cout. An output terminal of the driver circuit DRV is connected to a first input terminal such as an inverting input terminal of the error amplifier ERR.

The driver circuit DRV includes a first resistor R1 and a second resistor R2. A first terminal of the first resistor R1 is connected to the node between the second terminal of the inductor L and the first terminal of the capacitor Cout. A first terminal of the second resistor R2 is connected to a second terminal of the first resistor R1. A second terminal of the second resistor R2 is grounded.

The first input terminal, such as the inverting input terminal of the error amplifier ERR, is connected to a node between the first terminal of the second resistor R2 and the second terminal of the first resistor R1. A second input terminal, such as a non-inverting input terminal of the error amplifier, ERR is coupled with a reference voltage VREF.

A first input terminal such as a non-inverting input terminal of the comparator CMP is connected to an external ramp signal generator. A second input terminal such as an inverting input terminal of the comparator CMP is connected to an output terminal of the error amplifier ERR.

An output terminal of the comparator CMP of the feedback circuit FEB is connected to the duty cycle comparing circuit DCOMP of the frequency adjusting circuit FRQ. In the frequency adjusting circuit FRQ, the counter circuit COUNT is connected to the duty cycle comparing circuit DCOMP and the clock signal generator circuit CLK.

The control circuit CTR is connected to the clock signal generator circuit CLK and the duty cycle comparing circuit DCOMP of the frequency adjusting circuit FRQ, and is connected to the driver circuit DRV. The driver circuit DRV is connected to the control circuit CTR, the control terminal of the high-side switch HS and the control terminal of the low-side switch LS.

The first input terminal such as the inverting input terminal of the error amplifier ERR receives a feedback voltage VFB of the node between the first terminal of the second resistor R2 and the second terminal of the first resistor R1 of the driver circuit DRV. The feedback voltage VFB is a divided voltage of the output voltage VOUT of the power converter. The second input terminal, such as the non-inverting input terminal of the error amplifier ERR, receives the reference voltage VREF.

The error amplifier ERR multiples a difference between the feedback voltage VFB (that is the divided voltage of the output voltage VOUT of the power converter) and the reference voltage VREF by a gain to output an error amplified signal as the regulation on-time signal REGOT.

The first input terminal, such as the non-inverting input terminal of the comparator CMP, receives a ramp signal RAMP from the external ramp signal generator. The second input terminal, such as the inverting input terminal of the comparator CMP, receives an error amplified signal EAO from the output terminal of the error amplifier ERR.

The comparator CMP compares a voltage of the ramp signal RAMP with a voltage of the error amplified signal EAO to output a comparing signal as the regulation on-time signal REGOT.

It is worth noting that, each time when the duty cycle comparing circuit DCOMP of the frequency adjusting circuit FRQ receives the regulation on-time signal REGOT from the output terminal of the comparator CMP of the feedback circuit FEB as shown in FIG. 2, the frequency adjusting circuit FRQ performs processes S101 to S106 shown FIG. 4, described in detail as follows.

In the frequency adjusting circuit FRQ, the duty cycle comparing circuit DCOMP may be connected to the clock signal generator circuit CLK, and may receive a minimum on-time signal MINTON from the duty cycle comparing circuit DCOMP.

The duty cycle comparing circuit DCOMP compares the duty cycle of the waveform of the regulation on-time signal REGOT with a duty cycle of a waveform of the minimum on-time signal MINTON (in process S101).

Then, the duty cycle comparing circuit DCOMP determines whether or not the duty cycle of the waveform of the regulation on-time signal REGOT is larger than the duty cycle of the waveform of the minimum on-time signal MINTON (in process S102).

When the duty cycle comparing circuit DCOMP determines that the duty cycle of the waveform of the regulation on-time signal REGOT is larger than the duty cycle of the waveform of the minimum on-time signal MINTON, the duty cycle comparing circuit DCOMP does not output a duty cycle compared signal DCOMPS (or outputs the duty cycle compared signal DCOMPS at a non-trigger level such as a low level in practice) to the counter circuit COUNT. As a result, the counter circuit COUNT does not count up or down a count value (in process S103). Under this condition, the count value is maintained and is not adjusted. At this time, the counter circuit COUNT does not output a counting signal COUNTS according to the count value (or in practice, outputs the counting signal COUNTS that is the same as that outputted previously) to the clock signal generator circuit CLK.

Therefore, when the duty cycle comparing circuit DCOMP determines that the duty cycle of the waveform of the regulation on-time signal REGOT is larger than the duty cycle of the waveform of the minimum on-time signal MINTON, the clock signal generator circuit CLK does not adjust or reduce the frequency of the pulse wave of the clock signal SET, and outputs the clock signal SET that is not adjusted or reduced to the control circuit CTR (in process S103).

Furthermore, when the duty cycle comparing circuit DCOMP determines that the duty cycle of the waveform of the regulation on-time signal REGOT is larger than the duty cycle of the waveform of the minimum on-time signal MINTON, the duty cycle comparing circuit DCOMP may set and output a reset signal RESET to the control circuit CTR according to the regulation on-time signal REGOT from the output terminal of the comparator CMP of the feedback circuit FEB (in process S103).

For example, the duty cycle comparing circuit DCOMP starts generating a waveform of the reset signal RESET from a time point of a rising edge of the waveform of the regulation on-time signal REGOT.

Therefore, when the duty cycle comparing circuit DCOMP determines that the duty cycle of the waveform of the regulation on-time signal REGOT is larger than the duty cycle of the waveform of the minimum on-time signal MINTON, the control circuit CTR may drive the high-side switch HS and the low-side switch LS based on the clock signal SET in which the frequency of the pulse wave is maintained at the preset frequency and the reset signal RESET that is outputted according to the regulation on-time signal REGOT.

It is worth noting that, when the duty cycle comparing circuit DCOMP determines that the duty cycle of the waveform of the regulation on-time signal REGOT is not larger than the duty cycle of the waveform of the minimum on-time signal MINTON, the duty cycle comparing circuit DCOMP outputs the duty cycle compared signal DCOMPS (at a trigger level such as a high level). Then, the counter circuit COUNT adjusts the count value according to the duty cycle compared signal DCOMPS from the duty cycle comparing circuit DCOMP (in process S104). For example, the counter circuit COUNT counts up the count value for increasing the count value to output the counting signal COUNTS. Then, the clock signal generator circuit CLK adjusts (or reduces) the frequency of the clock signal SET according to the count value indicated in the counting signal COUNTS from the counter circuit COUNT (in process S104). For example, the clock signal generator circuit CLK adjusts the frequency of the clock signal SET from the preset frequency.

Furthermore, when the duty cycle comparing circuit DCOMP determines that the duty cycle of the waveform of the regulation on-time signal REGOT is not larger than the duty cycle of the waveform of the minimum on-time signal MINTON, the duty cycle comparing circuit DCOMP sets and outputs the reset signal RESET to the control circuit CTR according to the minimum on-time signal MINTON (in process S104).

For example, the duty cycle comparing circuit DCOMP starts generating the waveform of the reset signal RESET from a time point of a rising edge of the minimum on-time signal MINTON.

Therefore, when the duty cycle comparing circuit DCOMP determines that the duty cycle of the waveform of the regulation on-time signal REGOT is not larger than the duty cycle of the waveform of the minimum on-time signal MINTON, the control circuit CTR drives the high-side switch HS and the low-side switch LS based on the clock signal SET having the frequency that is adjusted (or reduced) and the reset signal RESET that is outputted according to the minimum on-time signal MINTON.

After the control circuit CTR drives the high-side switch HS and the low-side switch LS based on the clock signal SET having the frequency that is adjusted (or reduced), the duty cycle comparing circuit DCOMP may receive the regulation on-time signal REGOT from the output terminal of the comparator CMP of the feedback circuit FEB again. Then, the duty cycle comparing circuit DCOMP may determine whether or not the duty cycle of the waveform of the regulation on-time signal REGOT is equal to the duty cycle of the waveform of the minimum on-time signal MINTON (in process S105).

Then, when the duty cycle comparing circuit DCOMP determines that the duty cycle of the waveform of the regulation on-time signal REGOT is not equal to the duty cycle of the waveform of the minimum on-time signal MINTON, the duty cycle comparing circuit DCOMP outputs the duty cycle compared signal DCOMPS (at the trigger level such as the high level). Then, the counter circuit COUNT adjusts the count value according to the duty cycle compared signal DCOMPS from the duty cycle comparing circuit DCOMP again (in process S104). For example, the counter circuit COUNT counts up the count value for increasing the count value to output the counting signal COUNTS again. Then, the clock signal generator circuit CLK adjusts (or reduces) the frequency of the clock signal SET according to the count value indicated in the counting signal COUNTS from the counter circuit COUNT again (in process S104).

Furthermore, when the duty cycle comparing circuit DCOMP determines that the duty cycle of the waveform of the regulation on-time signal REGOT is not equal to the duty cycle of the waveform of the minimum on-time signal MINTON, the duty cycle comparing circuit DCOMP sets and outputs the reset signal RESET to the control circuit CTR according to the minimum on-time signal MINTON again (in process S104).

Conversely, when the duty cycle comparing circuit DCOMP determines that the duty cycle of the waveform of the regulation on-time signal REGOT is equal to the duty cycle of the waveform of the minimum on-time signal MINTON, the counter circuit COUNT does not count the count value, the duty cycle comparing circuit DCOMP does not output the duty cycle compared signal DCOMPS (or output the duty cycle compared signal DCOMPS at the non-trigger level such as the low level in practice) to the counter circuit COUNT. As a result, the counter circuit COUNT does not count up or down the count value (in process S103). Under this condition, the count value is maintained and is not adjusted. At this time, the counter circuit COUNT does not output the counting signal COUNTS according to the maintained count value (or in practice, outputs the counting signal COUNTS that is the same as that outputted previously) to the clock signal generator circuit CLK. Therefore, the clock signal generator circuit CLK does not adjust or reduce the frequency of the pulse wave of the clock signal SET outputted to the control circuit CTR (in process S106).

Furthermore, when the duty cycle comparing circuit DCOMP determines that the duty cycle of the waveform of the regulation on-time signal REGOT is equal to the duty cycle of the waveform of the minimum on-time signal MINTON, the duty cycle comparing circuit DCOMP sets or outputs the reset signal RESET to the control circuit CTR according to the regulation on-time signal REGOT or the minimum on-time signal MINTON. The control circuit CTR controls the driver circuit DRV to drive the high-side switch HS and the low-side switch LS according to the reset signal RESET.

When the duty cycle comparing circuit DCOMP determines that the duty cycle of the waveform of the regulation on-time signal REGOT is equal to the duty cycle of the waveform of the minimum on-time signal MINTON, the rising edge of the waveform of the regulation on-time signal REGOT is aligned with the rising edge of the waveform of the minimum on-time signal MINTON.

Conversely, when the duty cycle comparing circuit DCOMP determines that the duty cycle of the waveform of the regulation on-time signal REGOT is not equal to the duty cycle of the waveform of the minimum on-time signal MINTON, the rising edge of the waveform of the regulation on-time signal REGOT is not aligned with the rising edge of the waveform of the minimum on-time signal MINTON.

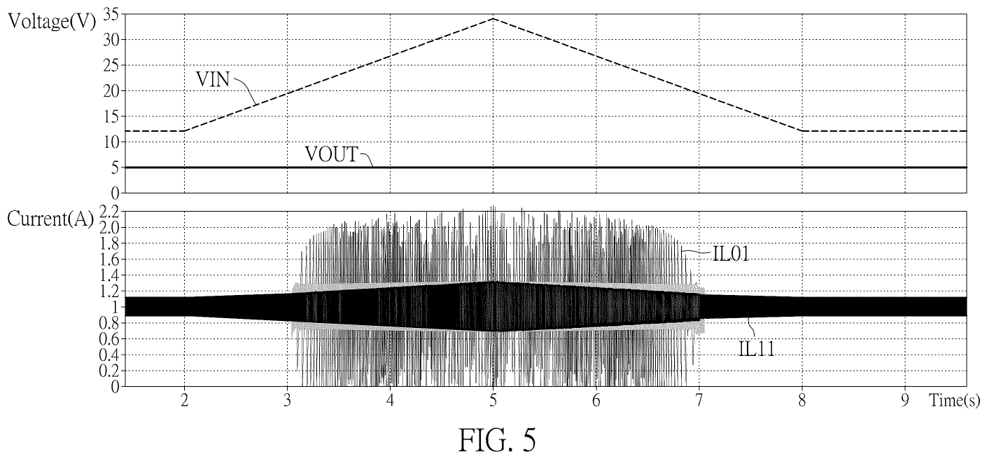

Reference is made to FIG. 5, which is a waveform diagram of signals of the first and second embodiments of the power converter and a conventional power converter.

The input voltage VIN coupled with the high-side switch HS of the power converter of the present disclosure as shown in FIG. 1 or FIG. 2 continues to be increased rapidly, the clock signal generator circuit CLK of the power converter of the present disclosure reduces the frequency of the pulse wave of the clock signal SET and outputs the pulse wave having the reduced frequency to the control circuit CTR for reducing a frequency of switching the high-side switch HS to an on state. As a result, the output voltage VOUT of the power converter of the present disclosure (that is, the node between the second terminal of the inductor L and the first terminal of the capacitor Cout) is able to be maintained at a constant voltage value as shown in FIG. 5.

The power converter of the present disclosure performs an adaptive frequency adjustment mechanism. As shown in FIG. 5, when the frequency of switching the high-side switch HS of the power converter of the present disclosure to the on state is reduced, only ripple waves each having a small amplitude are generated in a current signal IL11 of the inductor L of the power converter of the present disclosure.

In contrast, the conventional power converter performs a fixed frequency reduction mechanism. For example, the frequency of switching a high-side switch of the conventional power converter to an on-state is always reduced to ½ thereof. When the frequency of switching the high-side switch of the conventional power converter to the on-state, ripple waves each having a larger amplitude are generated in a current signal IL01 of an inductor of the conventional power converter.

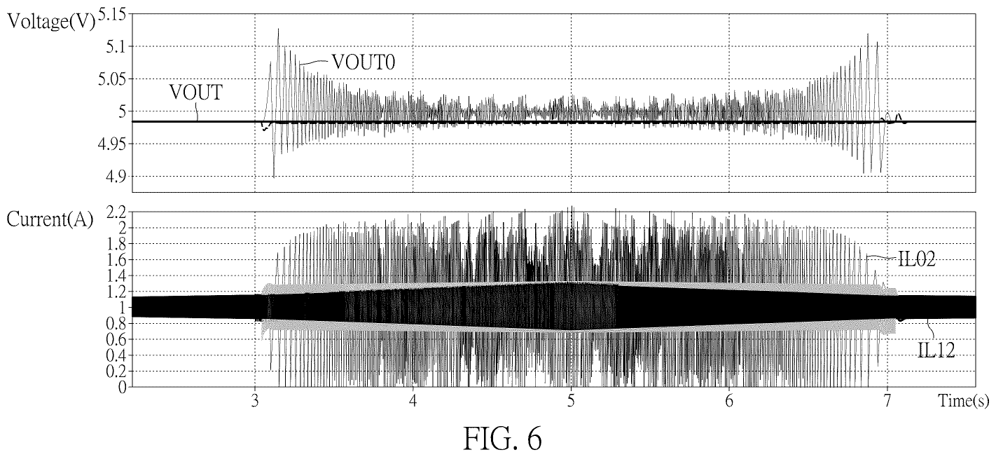

Reference is made to FIG. 6, which is a waveform diagram of signals of the first and second embodiments of the power converter and the conventional power converter.

The power converter of the present disclosure performs the adaptive frequency adjustment mechanism. When the input voltage VIN coupled with the high-side switch HS of the power converter of the present disclosure is continually increased, the clock signal generator circuit CLK reduces the frequency of the clock signal SET and outputs the clock signal SET having the reduced frequency to the control circuit CTR in the power converter of the present disclosure. As a result, in the power converter of the present disclosure, the frequency of switching the high-side switch HS to the on-state is reduced. Therefore, the output voltage VOUT of the power converter of the present disclosure (that is, the node between the second terminal of the inductor L and the first terminal of the capacitor Cout) is able to be maintained at a constant voltage value as shown in FIG. 6.

In contrast, the conventional power converter performs the fixed frequency reduction mechanism. For example, the frequency of switching the high-side switch of the conventional power converter to the on-state is always reduced to ½ thereof. When the frequency of switching the high-side switch of the conventional power converter to the on-state is reduced, ripple waves each having a larger amplitude are generated in an output voltage VOUT0 of the conventional power converter as shown in FIG. 6.

In addition, as shown in FIG. 5, when the frequency of switching the high-side switch HS of the power converter of the present disclosure to the on-state is reduced, only ripple waves each having a small amplitude are generated in a current signal IL12 of the inductor L.

In contrast, when the frequency of switching the high-side switch of the conventional power converter to the on-state is reduced, ripple waves each having a larger amplitude are generated in a current signal IL02 of the inductor of the conventional power converter.

The number of the ripple waves generated in a signal of the output voltage VOUT of the power converter of the present disclosure is much smaller than the number of the ripple waves generated in a signal of the output voltage VOUT of the conventional power converter. Therefore, stability of the power converter of the present disclosure that performs the adaptive frequency adjustment mechanism is higher than stability of the conventional power converter using the fixed frequency reduction mechanism.

In conclusion, the present disclosure provides the power converter for adaptively adjusting the frequency. In the power converter of the present disclosure, the frequency of switching the high-side switch and the low-side switch is able to be appropriately adjusted with the change in the input voltage. Under this condition, soft switching is able to be efficiently performed on the high-side switch and the low-side switch. The output voltage of the power converter of the present disclosure is prevented from dropping instantaneously. As a result, the number of the ripple waves in the output voltage of the power converter of the present disclosure is reduced. Therefore, the stability of the output voltage of the power converter of the present disclosure is improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power converter that adaptively adjusts a frequency, comprising:
a high-side switch, wherein a first terminal of the high-side switch is coupled with an input voltage;
a low-side switch, wherein a first terminal of the low-side switch is connected to a second terminal of the low-side switch, a second terminal of the low-side switch is grounded, a node between the first terminal of the low-side switch and the second terminal of the high-side switch is connected to a first terminal of an inductor, a second terminal of the inductor is connected to a first terminal of a capacitor, and a second terminal of the capacitor is grounded;
a feedback circuit connected to a node between the second terminal of the inductor and the first terminal of the capacitor, and configured to output a regulation on-time signal according to a voltage signal of the node between the second terminal of the inductor and the first terminal of the capacitor;
a frequency adjusting circuit connected to the feedback circuit, wherein, when the frequency adjusting circuit determines that a duty cycle of a waveform of the regulation on-time signal is not larger than a duty cycle of a waveform of a minimum on-time signal, the frequency adjusting circuit adjusts a frequency of a clock signal and outputs the clock signal having the frequency that is adjusted;
a control circuit connected to the frequency adjusting circuit, and configured to output a control signal according to the clock signal from the frequency adjusting circuit; and
a driver circuit connected to the control circuit, a control terminal of the high-side switch and a control terminal of the low-side switch, and configured to drive the high-side switch and the low-side switch according to the control signal from the control circuit.

2. The power converter according to claim 1, wherein the control circuit, according to a change in the clock signal from the frequency adjusting circuit, sets a width of a pulse wave of a pulse width modulation signal and outputs the pulse width modulation signal as the control signal to the driver circuit.

3. The power converter according to claim 1, wherein the feedback circuit includes:
an error amplifier, wherein a first input terminal of the error amplifier is connected to the node between the second terminal of the inductor and the first terminal of the capacitor, and a second input terminal of the error amplifier is coupled with a reference voltage; and
a comparator, wherein a first input terminal of the comparator receives a ramp signal from an external ramp signal generator connected thereto, a second input terminal of the comparator is connected to an output terminal of the error amplifier, an output terminal of the comparator is connected to the frequency adjusting circuit, and the comparator outputs a comparing signal to the frequency adjusting circuit as the regulation on-time signal.

4. The power converter according to claim 3, wherein the feedback circuit further includes:
a voltage divider circuit, wherein an input terminal of the voltage divider circuit is connected to the node between the second terminal of the inductor and the first terminal of the capacitor, and an output terminal of the voltage divider circuit is connected to the first input terminal of the error amplifier.

5. The power converter according to claim 4, wherein the voltage divider circuit includes:
a first resistor, wherein a first terminal of the first resistor is connected to the node between the second terminal of the inductor and the first terminal of the capacitor; and
a second resistor, wherein a first terminal of the second resistor is connected to a second terminal of the first resistor, a second terminal of the second resistor is grounded, and a node between the first terminal of the second resistor and the second terminal of the first resistor is connected to the first input terminal of the error amplifier.

6. The power converter according to claim 3, wherein the frequency adjusting circuit includes:
a duty cycle comparing circuit connected to the output terminal of the comparator, and configured to output a duty cycle compared signal when the duty cycle comparing circuit determines that the duty cycle of the waveform of the regulation on-time signal from the comparator is not larger than the duty cycle of the waveform of the minimum on-time signal;
a counter circuit connected to the duty cycle comparing circuit, and configured to count a count value to output a counting signal according to the duty cycle comparing circuit from the duty cycle comparing circuit; and
a clock signal generator circuit connected to the counter circuit, and configured to adjust a frequency of the clock signal according to the counting signal from the counter circuit and output the clock signal that is adjusted to the control circuit.

7. The power converter according to claim 6, wherein, each time when the counter circuit determines to count the count value according to the duty cycle compared signal from the duty cycle comparing circuit, the counter circuit counts up the count value once to increase the count value once and outputs the counting signal according to the count value that is increased.

8. The power converter according to claim 6, wherein the clock signal generator circuit is connected to the duty cycle comparing circuit and configured to output the minimum on-time signal to the duty cycle comparing circuit.

9. The power converter according to claim 6, wherein, each time when the duty cycle of the waveform of the regulation on-time signal is not larger than the duty cycle of the waveform of the minimum on-time signal, the clock signal generator circuit reduces the frequency of the clock signal.

10. The power converter according to claim 6, wherein, each time when the duty cycle of the waveform of the regulation on-time signal is larger than the duty cycle of the waveform of the minimum on-time signal, the counter circuit does not adjust the count value.

11. The power converter according to claim 10, wherein, when the count value is not adjusted by the counter circuit, the frequency of the clock signal is not adjusted by the clock signal generator circuit.

12. The power converter according to claim 6, wherein the duty cycle comparing circuit is connected to the control circuit;
wherein, when the duty cycle comparing circuit determines that the duty cycle of the waveform of the regulation on-time signal is larger than the duty cycle of the waveform of the minimum on-time signal, the duty cycle comparing circuit outputs a reset signal to the control circuit according to the regulation on-time signal, and the control circuit controls the driver circuit according to the reset signal.

13. The power converter according to claim 12, wherein the duty cycle comparing circuit starts generating a waveform of the reset signal from a time point of a rising edge of the waveform of the regulation on-time signal.

14. The power converter according to claim 6, wherein the duty cycle comparing circuit is connected to the control circuit;
wherein, when the duty cycle comparing circuit determines that the duty cycle of the waveform of the regulation on-time signal is not larger than the duty cycle of the waveform of the minimum on-time signal, the duty cycle comparing circuit outputs a reset signal to the control circuit according to the minimum on-time signal, and the control circuit controls the driver circuit according to the reset signal.

15. The power converter according to claim 14, wherein the reset signal starts generating a waveform of the reset signal from a time point of a rising edge of the waveform of the regulation on-time signal.

16. The power converter according to claim 6, wherein, after the control circuit controls the driver circuit to drive the high-side switch and the low-side switch according to the clock signal having the frequency that is adjusted, the duty cycle comparing circuit receives the regulation on-time signal from the comparator, and the duty cycle comparing circuit determines whether the duty cycle of the waveform of the regulation on-time signal is equal to the duty cycle of the waveform of the minimum on-time signal.

17. The power converter according to claim 16, wherein, when the duty cycle comparing circuit determines that the duty cycle of the waveform of the regulation on-time signal is equal to the duty cycle of the waveform of the minimum on-time signal, the counter circuit does not count the count value and the clock signal generator circuit does not adjust the frequency of the clock signal.

18. The power converter according to claim 16, wherein, when the duty cycle comparing circuit determines that the duty cycle of the waveform of the regulation on-time signal is equal to the duty cycle of the waveform of the minimum on-time signal, the duty cycle comparing circuit outputs a reset signal to the control circuit according to the regulation on-time signal or the minimum on-time signal, and the control circuit controls the driver circuit according to the reset signal.

19. The power converter according to claim 18, wherein the duty cycle comparing circuit starts generating a waveform of the reset signal from a time point of a rising edge of the waveform of the regulation on-time signal or the minimum on-time signal.

20. The power converter according to claim 1, wherein, when the input voltage is increased or decreased, a voltage signal of the node between the second terminal of the inductor and the first terminal of the capacitor is maintained at a constant voltage value.
